(19) United States
(12) Patent Application Publication
(10) Pub. No.: US 2021/0267031 A1
(43) Pub. Date: Aug. 26, 2021

(54) LOAD CONTROL SYSTEM AND PROGRAM

(71) Applicant: Panasonic Intellectual Property Management Co., Ltd., Osaka (JP)

(72) Inventors: Kengo MIYAMOTO, Osaka (JP); Kota MAEBA, Mie (JP)

(21) Appl. No.: 17/261,634

(22) PCT Filed: Jul. 16, 2019
(86) PCT No.: PCT/JP2019/027873

§ 371 Date: Jan. 20, 2021

(30) Foreign Application Priority Data
Jul. 27, 2018 (JP) 2018-141595

(51) Int. Cl. H05B 45/14; H05B 45/34

(52) U.S. Cl. CPC H05B 45/14; H05B 45/34

(57) ABSTRACT

A load control system includes a switch, a controller, an additional functioning unit, a power source, and an adjuster. The controller is configured to switch the switch between a conduction state and a non-conduction state. The switch is electrically connected in series to a load with respect to an alternating-current power source. The additional functioning unit is configured to perform a process different from switching operation of the switch. The power source receives electric power supplied from the alternating-current power source to generate electric power to be supplied to the controller and the additional functioning unit. The adjuster adjusts a supply time period during which the power source is supplied with electric power from the alternating-current power source in a maximum load state of a state where the additional functioning unit normally operates, electric power consumption by the additional functioning unit being maximum in the maximum load state.

### TECHNICAL FIELD

The present disclosure relates to load control systems and programs. Specifically, the present disclosure relates to a load control system and a program that perform phase control of an alternating-current voltage supplied to a load.

### BACKGROUND ART

A light control device for dimming an illumination load has been known (e.g., Patent Literature 1).

The light control device described in Patent Literature 1 includes a pair of terminals, a control circuit, and a control power source configured to supply control electric power to the control circuit.

The control circuit and the control power source are connected in parallel to each other between the pair of terminals. Moreover, between the pair of terminals, a series circuit of an alternating-current power source and the illumination load is connected. The illumination load includes a plurality of Light Emitting Diode (LED) elements and a power supply circuit configured to turn on each of the LED elements. The power supply circuit includes a smoothing circuit of a diode and an electrolytic capacitor.

The control circuit includes a switch section configured to perform phase control of an alternating-current voltage supplied to the illumination load, a switch driver configured to drive the switch section, and a controller configured to control the switch driver and the control power source.

The control power source is connected in parallel to the switch section. The control power source is configured to convert an alternating-current voltage of the alternating-current power source into the control electric power. The control power source includes an electrolytic capacitor configured to accumulate the control electric power.

The controller is supplied with the control electric power from the control power source (a power source) through the electrolytic capacitor. The controller performs reverse phase control of cutting off power supply to the illumination load in a time period of each half cycle of the alternating-current voltage in accordance with dimming levels set by a dimming operation unit.

In the light control device described in Patent Literature 1, the control power source (the power source) converts the alternating-current voltage of the alternating-current power source into the control electric power and accumulates the control electric power in the electrolytic capacitor during a time period during which the switch section (switch) is OFF. The control power source supplies the electric power accumulated during the time period during which the switch section is OFF to cover electric power consumption by the control circuit during all time periods. Therefore, when the electric power consumption by the control circuit (a controller and an additional functioning unit) increases, the electric power supplied by the control power source may be insufficient.

### CITATION LIST

### Patent Literature

Patent Literature 1: JP 2013-149495 A

### SUMMARY OF INVENTION

An object of the present disclosure is to provide a load control system and a program that are configured to reduce the possibility that electric power supplied by a power source is insufficient.

A load control system of one aspect of a present disclosure includes a switch, a controller, an additional functioning unit, a power source, and an adjuster. The switch is electrically connected in series to a load with respect to an alternating-current power source and is configured to perform phase control of an alternating-current voltage supplied to the load. The controller is configured to switch the switch between a conduction state and a non-conduction state. The additional functioning unit is configured to perform a process different from a switching operation of the switch. The power source is configured to receive electric power supplied from the alternating-current power source to generate electric power supplied to the controller and the additional functioning unit. The adjuster is configured to adjust, in a maximum load state, a supply time period during which the power source is supplied with the electric power from the alternating-current power source. The maximum load state is a state where electric power consumption by the additional functioning unit is maximum in a state where the additional functioning unit normally operates.

A program of another aspect of the present disclosure is a program configured to cause a computer system to execute a first process, a second process, and a third process. The first process is a process of switching a switch between a conduction state and a non-conduction state. The switch is electrically connected in series to a load with respect to an alternating-current power source to perform phase control of the alternating-current voltage supplied to the load. The second process is a process of causing an additional functioning unit to execute a process different from a switching operation of the switch. The third process is a process of adjusting, in a maximum load state, a supply time period during which a power source is supplied with electric power from the alternating-current power source. The maximum load state is a state where electric power consumption by the additional functioning unit is maximum in a state where the additional functioning unit normally operates. The power source is configured to receive the electric power supplied from the alternating-current power source to generate electric power supplied to the additional functioning unit.

### BRIEF DESCRIPTION OF DRAWINGS

FIG. 1 is a block circuit diagram illustrating a load control system according to one embodiment of the present disclosure;

FIG. 2 is a front view illustrating the load control system with a front cover being removed;

FIG. 3 is a waveform diagram of each of components of the load control system;

FIG. 4 is a circuit diagram of a power source included in the load control system;

FIG. 5 is a flowchart illustrating operation of the load control system;

FIG. 6A is a waveform diagram of a load voltage and a charging current upon activation;

FIG. 6B is a waveform diagram illustrating the load voltage and the charging current after a supply time period is adjusted.

### DESCRIPTION OF EMBODIMENTS

### Embodiment

(1) Schema

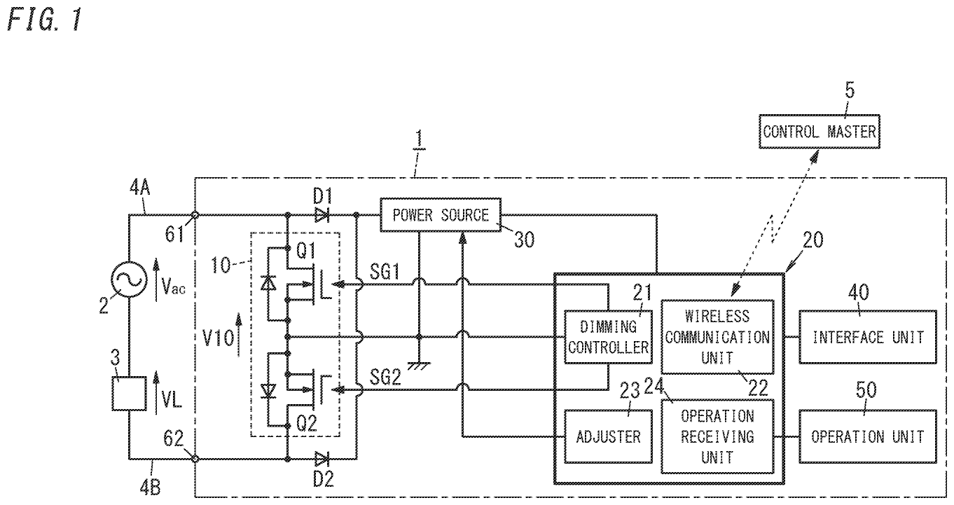

As illustrated in FIG. 1, a load control system 1 according to the present embodiment includes a switch 10 electrically connected in series to a load 3 with respect to an alternating-current power source 2. The load control system 1 performs, by the switch 10, phase control of an alternating-current voltage Vac supplied from the alternating-current power source 2 to the load 3. As used herein, “phase control” means a method of controlling the alternating-current voltage Vac by varying the alternating-current voltage Vac supplied (applied) to the load 3 by changing each of a phase angle (a conduction angle) at which energization of the load 3 is started and a phase angle at which the energization of the load 3 is ended for each half period of the alternating-current voltage Vac. That is, the load control system 1 performs phase control of the alternating-current voltage Vac supplied to the load 3 to control the load 3 such as an illumination load, a heater, or a fan.

In the present embodiment, an example will be described in which the load 3 is an illumination load including a plurality of LED elements and a lighting circuit configured to turn on the plurality of LED elements. That is, the load control system 1 constitutes a dimming device configured to adjust, by the phase control, the intensity of light output from the load 3, which is the illumination load. Here, the lighting circuit of the load 3 reads a dimming level from the waveform of the alternating-current voltage Vac after the phase control performed by the load control system 1 and changes the intensity of light output from the LED elements. The lighting circuit of the load 3 includes, for example, a circuit, such as a bleeder circuit, for securing a current. Thus, even during a time period during which the switch 10 of the load control system 1 is in a non-conduction state, causing a current to flow to the load 3 is possible. The alternating-current power source 2 is, for example, a single phase 100 V, 60 Hz commercial power supply.

Here, the load control system 1 of the present embodiment is a two-wire system and is electrically connected between the alternating-current power source 2 and the load 3 such that the switch 10 is electrically connected in series to the load 3 with respect to the alternating-current power source 2. In other words, two electric wires 4A and 4B, that is, the electric wire 4A connected to the alternating-current power source 2 and the electric wire 4B connected to the load 3 are connected to the load control system 1, and the switch 10 is inserted between these two electric wires 4A and 4B. Thus, when the switch 10 is in a conduction state, the alternating-current voltage Vac from the alternating-current power source 2 is applied to the load 3, thereby supplying electric power to the load 3. When the switch 10 is in the non-conduction state, the alternating-current voltage Vac from the alternating-current power source 2 is applied to the load control system 1 thereby stopping electric power supply to the load 3. The load control system 1 obtains electric power supply for operation of the load control system 1 itself through these two electric wires 4A and 4B from the alternating-current power source 2, thereby performing, for example, control of the switch 10. That is, when the switch 10 is in the non-conduction state, the load control system 1 generates, by a power source 30 described later, the electric power for operation of itself, and therefore, a two-wire load control system 1 can be constructed.

The load control system 1 according to the present embodiment includes the switch 10, a controller (e.g., a dimming controller 21), an additional functioning unit (e.g., a wireless communication unit 22), the power source 30, and an adjuster 23.

The controller (the dimming controller 21) switches the switch 10 between the conduction state and the non-conduction state. Here, phase control of the alternating-current voltage Vac supplied (applied) to the load 3 is performed by switching the switch 10 between the conduction state and the non-conduction state, and operation that the switch 10 controls the alternating-current voltage Vac supplied (applied) to the load 3 is referred to as switching operation.

The additional functioning unit (the wireless communication unit 22) performs a process different from the switching operation of the switch 10. As used herein, “a process different from the switching operation” is a process for implementing functions other than the switching operation of the additional functioning unit. The following embodiment will describe an example in which the additional functioning unit is the wireless communication unit 22 and the process different from the switching operation is a process of wirelessly performing communication.

The power source 30 receives electric power supplied from the alternating-current power source 2 to generate electric power to be supplied to the controller (the dimming controller 21) and the additional functioning unit (the wireless communication unit 22).

The adjuster 23 adjusts, in a maximum load state, a supply time period during which the power source 30 is supplied with the electric power from the alternating-current power source 2. The maximum load state is a state where electric power consumption by the additional functioning unit (the wireless communication unit 22) is maximum in a state where the additional functioning unit (the wireless communication unit 22) normally operates. Here, “a state where the additional functioning unit normally operates” refers to a state where the additional functioning unit operates in a state where the function of the additional functioning unit is implementable. in the state where the additional functioning unit (the wireless communication unit 22) normally operates, the “maximum load state” where the electric power consumption by the additional functioning unit (the wireless communication unit 22) is maximum refers to a state where the electric power consumption is maximum except for a state where the electric power consumption by the additional functioning unit (the wireless communication unit 22) increases due to a failure or the like. The supply time period during which the power source 30 is supplied with the electric power from the alternating-current power source 2 is a time period during which, for each half period of the alternating-current voltage Vac, the power source 30 is supplied with electric power from the alternating-current power source 2 to generate the electric power to be supplied to the controller (the dimming controller 21) and the additional functioning unit (the wireless communication unit 22).

As described above, the power source 30 generates, during a time period during which the switch 10 is in the non-conduction state, the electric power to be supplied to the controller (the dimming controller 21) and the additional functioning unit (the wireless communication unit 22), and the power source 30 covers, with the electric power generated during this time period, electric power required during a total time period. In the load control system 1 of the present embodiment, the adjuster 23 adjusts a supply time period during which the power source 30 is supplied with the electric power from the alternating-current power source 2 in the maximum load state. Thus, as long as the supply time period is adjusted such that the electric power supplied by the power source 30 is not insufficient in the maximum load state, it is possible to reduce the possibility that the electric power supplied by the power source 30 becomes insufficient when electric power consumption by the additional functioning unit (the wireless communication unit 22) varies. Moreover, when the supply time period is increased at a timing at which the electric power consumption by the additional functioning unit (the wireless communication unit 22) increases, adjusting the supply time period may reduce a time period during which the switch 10 is in the conduction state, so that the output of the load may vary. In contrast, in the present embodiment, the adjuster 23 adjusts the supply time period in the maximum load state, and the supply time period is not adjusted each time the electric power consumption by the additional functioning unit (the wireless communication unit 22) varies, and therefore, the output from the load is suppressed from varying.

(2) Details

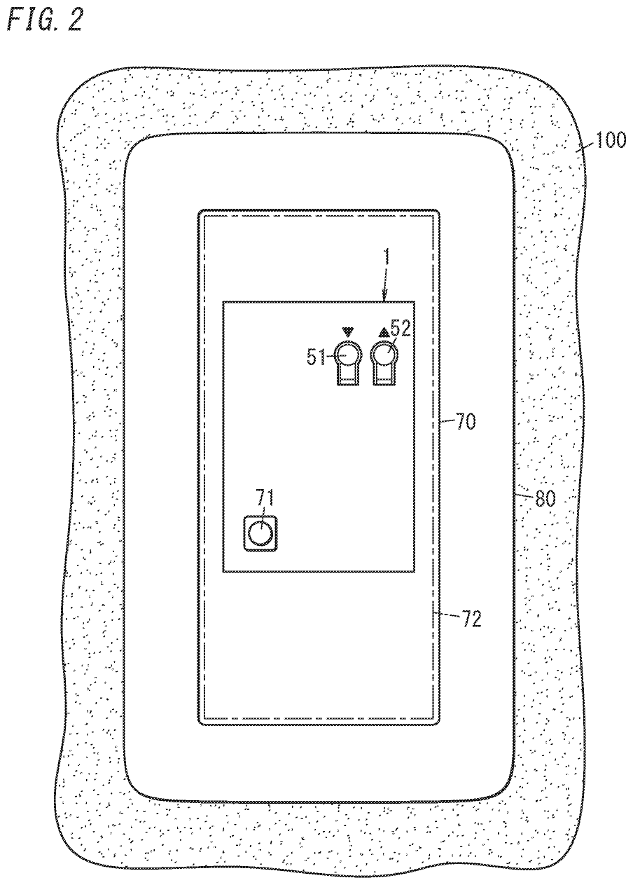

As illustrated in FIG. 1, the load control system 1 according to the present embodiment includes the switch 10, the power source 30, and a processing circuit 20. Moreover, the load control system 1 according to the present embodiment includes a pair of input terminals 61 and 62, diodes D1 and D2, an interface unit 40, and an operation unit 50. The processing circuit 20 has functions as the controller (the dimming controller 21), the additional functioning unit (the wireless communication unit 22), and the adjuster 23. The processing circuit 20 further has a function as an operation receiving unit 24 configured to receive an operation given by a user to the operation unit 50. As used herein, the “input terminal” does not have to be a component (terminal) for connecting an electric wire and the like but may be, for example, a lead of an electronic component or part of a conductor included in a circuit board. The load control system 1 of the present embodiment is applicable to, for example, a wall switch. As illustrated in FIG. 2, the load control system 1 has a housing 70 attachable to a building material 100 such as a wall with a frame member. The housing 70 has a front surface exposed from an opening formed in a decoration frame 80 to be attached to a front side of the frame member. Note that on to a front side of the housing 70 shown in FIG. 2, a front cover 72 provided with a touch panel included in the interface unit 40 described later is attached.

The switch 10 includes two switch elements Q1 and Q2 electrically connected in series to each other, for example, between the input terminals 61 and 62. For example, each of the switch elements Q1 and Q2 is a semiconductor switch element including a Metal-Oxide-Semiconductor Field Effect Transistor (MOSFET).

The switch elements Q1 and Q2 are connected in a so-called anti-series connection between the input terminals 61 and 62. That is, the sources of the switch elements Q1 and Q2 are connected to each other. The drain of the switch element Q1 is connected to the input terminal 61, and the drain of the switch element Q2 is connected to the input terminal 62. The sources of both the switch elements Q1 and Q2 are connected to ground of the power source 30. Here, the ground of the power source 30 is a reference potential for an internal circuit of the load control system 1.

The switch 10 is switchable among four states by combinations of ON and OFF of the switch elements Q1 and Q2. Each of the switch elements Q1 and Q2 is switched ON or OFF by the dimming controller 21. Here, the four states include a “bidirectionally OFF state” where both the switch elements Q1 and Q2 are OFF, a “bidirectionally ON state” where both of the switch elements Q1 and Q2 are ON, and two types of “unidirectionally ON state” where only one of the switch elements Q1 and Q2 is ON. In the unidirectionally ON state, unidirectional conduction is achieved between the pair of input terminals 61 and 62 from one switch element of the switch elements Q1 and Q2 which is ON through a parasitic diode of the other switch element which is OFF. For example, in a state where the switch element Q1 is ON and the switch element Q2 is OFF, a “first unidirectionally ON state” is achieved where a current is caused to flow from the input terminal 61 toward the input terminal 62. Moreover, in a state where the switch element Q2 is ON and the switch element Q1 is OFF, a “second unidirectionally ON state” is achieved where a current is caused to flow from the input terminal 62 toward the input terminal 61. Therefore, when the alternating-current voltage Vac is applied between the input terminals 61 and 62 from the alternating-current power source 2, the first unidirectionally ON state is a “forward ON state” and the second unidirectionally ON state is a “reverse ON state” in a half period of positive polarity of the alternating-current voltage Vac, that is, in a half period in which the input terminal 61 is positive. On the other hand, the second unidirectionally ON state is the “forward ON state”, and the first unidirectionally ON state is the “reverse ON state” in a half period of negative polarity of the alternating-current voltage Vac, that is, in a half period in which the input terminal 62 is positive.

Here, in both the “bidirectionally ON state” and the “forward ON state”, the switch 10 is in the “conduction state” where a current flows through the switch 10 to the load 3. In both the “bidirectionally OFF state” and the “reverse ON state”, the switch 10 is in the “non-conduction state” where no current flows through the switch 10 to the load 3. Thus, the dimming controller 21 performs control, in a positive half period or a negative half period of the alternating-current voltage Vac, such that each of the switch elements Q1 and Q2 is ON or OFF to switch the switch 10 to the “conduction state” or the “non-conduction state”.

The interface unit 40 receives an input level that specifies a phase angle (a conduction angle) at which energization of the load 3 is started or ended for each half period of the alternating-current voltage Vac. That is, the input level specifies a timing at which the switch 10 is switched to the conduction state or a timing at which the switch 10 is switched to the non-conduction state in the half period of the alternating-current voltage Vac. In the present embodiment, the load control system 1 is the dimming device, and therefore, the interface unit 40 receives an operation given by a user and receives an input of a dimming level as the input level. The interface unit 40 outputs a dimming signal representing the dimming level to the processing circuit 20. The dimming signal is a numerical value or the like specifying the intensity of light output from the load 3 and may include an “OFF level” at which the load 3 is in a non-lighting state. In the present embodiment, for example, the interface unit 40 includes a touch panel configured to receive a touch operation given by a user. The touch panel is held by the front cover 72 to be attached to the front side of the housing 70 and is configured to receive a touch operation given by a user in a state where the housing 70 of the load control system 1 is attached to the building material 100 such as a wall or the like. Note that the interface unit 40 is at least configured to output a signal representing the input level (the dimming level) and may be, for example, a variable resistor or a rotary switch. Moreover, the interface unit 40 may be configured as a receiver that receives a signal from a communication terminal such as a remote controller or a smartphone.

As illustrated in FIG. 2, the operation unit 50 includes a pair of operation buttons 51 and 52 disposed on, for example, a front surface of the housing 70 of the load control system 1. The operation buttons 51 and 52 are covered with the front cover 72 in a state where the front cover 72 is attached to the front side of the housing 70. Thus, in the state where the front cover 72 is attached to the front side of the housing 70, it is not possible to operate the operation buttons 51 and 52, and in a state where the front cover 72 is removed, it is possible to operate the operation buttons 51 and 52. The operation button 51 is a button operated by a user, for example, when the supply time period during which the power source 30 is supplied with the electric power from the alternating-current power source 2 is to be increased. The operation button 52 is a button operated by a user, for example, when the supply time period during which the power source 30 is supplied with the electric power from the alternating-current power source 2 is to be reduced.

Moreover, a display lamp 71 including, for example, an LED is disposed on the front surface of the housing 70. When the adjuster 23 adjusts the supply time period, the processing circuit 20 determines whether or not the power source 30 generates required electric power necessary for operation of the dimming controller 21 and the wireless communication unit 22. When the power source 30 does not generate the required electric power necessary for operation of the dimming controller 21 and the wireless communication unit 22, the processing circuit 20 turns on the display lamp 71. In contrast, when the power source 30 generates the required electric power necessary for operation of the dimming controller 21 and the wireless communication unit 22, the processing circuit 20 turns off the display lamp 71. Thus, a user can operate the operation unit 50 while checking the state of the display lamp 71 to adjust the supply time period such that the power source 30 generates the required electric power necessary for operation of the dimming controller 21 and the wireless communication unit 22.

Moreover, the interface unit 40 further includes a display section (an indicator) configured to display the input level (the dimming level) thus input. The interface unit 40 includes a display section including, for example, a plurality of LED elements and displays the input level by the number of LED elements turned on.

As described above, the processing circuit 20 has functions as the dimming controller 21, the wireless communication unit 22, the adjuster 23, the operation receiving unit 24, and the like. The processing circuit 20 includes, for example, as a main component, a microcontroller including one or more processors and one or more memories. The one or more processors of the microcontroller execute one or more programs stored in the one or more memories of the microcontroller, thereby implementing the functions of the processing circuit 20. The one or more programs may be stored in the one or more memories, provided via a telecommunications network such as the Internet, or provided by a non-transitory storage medium such as a memory card storing the one or more programs. Each of the functions of the processing circuit 20 will be described below. Note that in the present embodiment, the processing circuit 20 has functions as the dimming controller 21 and the wireless communication unit 22, but the dimming controller 21 which is the controller and the wireless communication unit 22 which is the additional functioning unit may be configured as separate components.

The processing circuit 20 includes the wireless communication unit 22 as the additional functioning unit for performing the process different from the switching operation. The wireless communication unit 22 is a communication module that performs communication based on a near field communication method which requires no license of a wireless station. In the present embodiment, the wireless communication unit 22 is a communication module conforming to a specified low power radio communication standard. The wireless communication unit 22 intermittently performs communication with, for example, a control master 5 based on a wireless communication method. The wireless communication unit 40 intermittently stands by for reception of a radio signal transmitted from the control master 5 at an arbitrary timing. When the wireless communication unit 22 receives the radio signal from the control master 5, the processing circuit 20 operates in accordance with the radio signal received by the wireless communication unit 22. Moreover, the processing circuit 20 may cause a response signal to the radio signal from the control master 5 to be transmitted from the wireless communication unit 22 to the control master 5. For example, when the control master 5 transmits a radio signal including a control signal of the load 3 (e.g., a dimming signal of the load 3), the processing circuit 20 controls the load 3 in accordance with the control signal received by the wireless communication unit 22 and causes a control result as a response signal to be transmitted from the wireless communication unit 22 to the control master 5. In the present embodiment, the wireless communication unit 22 which is the additional functioning unit intermittently operates, and therefore, electric power consumption by the wireless communication unit 22 is not constant. During transmission by the wireless communication unit 22, electric power consumption by the wireless communication unit 22 increases. Moreover, when deterioration of a surrounding noise environment increases communication errors, the number of reception and the number of times of transmission performed by the wireless communication unit 22 increase, so that the electric power consumption by the wireless communication unit 22 further increases. Note that the wireless communication unit 22 is not limited to the communication module conforming to the specified low power radio communication standard but may be a communication module conforming to a communication standard such as Bluetooth (registered trademark) or Wi-Fi (registered trademark).

The dimming controller 21 detects the phase of the alternating-current voltage Vac applied between the input terminals 61 and 62, and based on the detection result of the phase of the alternating-current voltage Vac, the dimming controller 21 switches the switch 10 between the conduction state and the non-conduction state, thereby performing phase control of the alternating-current voltage Vac supplied to the load 3. As used herein, “phase” includes the zero crossing point of the alternating-current voltage Vac and the polarities (positive polarity and negative polarity) of the alternating-current voltage Vac. The dimming controller 21 detects a zero crossing point when the alternating-current voltage Vac transitions from the negative half period to the positive half period based on, for example, a voltage obtained by dividing the voltage of the input terminal 61 by a resistor voltage dividing circuit including a plurality of resistors. In addition, the dimming controller 21 detects a zero crossing point when the alternating-current voltage Vac transitions from the positive half period to the negative half period based on, for example, a voltage obtained by dividing the voltage of the input terminal 62 by a resistor voltage dividing circuit including a plurality of resistors. Here, the zero crossing point is not limited to the zero crossing point (0 V) in a strict sense. The zero crossing point when the alternating-current voltage Vac transitions from the negative half period to the positive half period may be, for example, a point at which the alternating-current voltage Vac is higher than a positive threshold set around 0 V. Moreover, the zero crossing point when the alternating-current voltage Vac transitions from the positive half period to the negative half period may be, for example, a point at which the alternating-current voltage Vac is lower than a negative threshold set around 0 V. Thus, the detection point of the zero crossing point detected by the dimming controller 21 may be slightly delayed from the zero crossing point (0 V) in a strict sense.

The dimming controller 21 controls the switch 10 based on the detection result of the zero crossing point and a dimming signal from the interface unit 40 or the wireless communication unit 22. The dimming controller 21 individually controls the switch elements Q1 and Q2 to switch the switch 10 between the conduction state and the non-conduction state. Specifically, the dimming controller 21 controls the switch element Q1 by a first control signal SG1 and controls the switch element Q2 by a second control signal SG2 to individually control the switch elements Q1 and Q2.

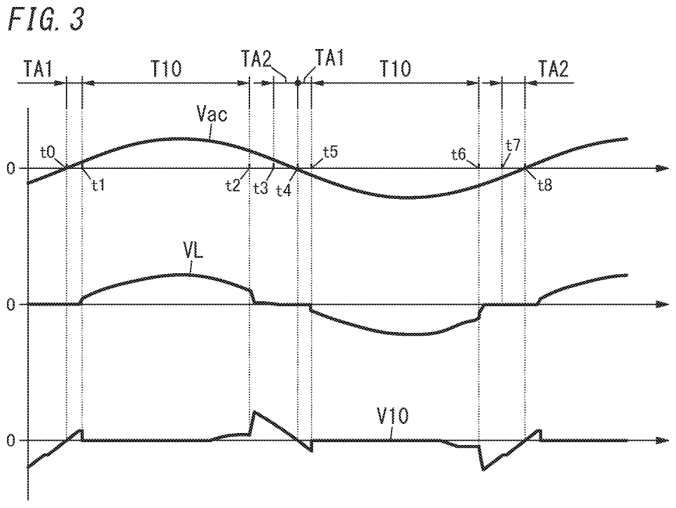

In the present embodiment, the dimming controller 21 performs “reverse phase control” of cutting off power supply to the load 3 in a time period of each half period of the alternating-current voltage Vac. FIG. 3 shows an alternating-current voltage “Vac”, a load voltage “VL” applied to the load 3, and a voltage “V10” across the switch 10 when the dimming controller 21 performs the reverse phase control. The dimming controller 21 switches the switch 10 to the conduction state at a timing (time t1, t5) at which a first supply time period TA1 set by the adjuster 23 has elapsed since a zero crossing point (time t0, t4) for each half cycle of the alternating-current voltage Vac, thereby supplying electric power to the load 3. The dimming controller 21 switches the switch 10 to the non-conduction state at a timing (time t2, t6) at which a time period T10 has elapsed since the switch 10 is switched to the conduction state, thereby cutting off power supply to the load 3. The duration of the time period T10 is a duration according to the dimming signal from the interface unit 40 or the wireless communication unit 22. This enables the dimming controller 21 to supply, based on the dimming signal from the interface unit 40 or the wireless communication unit 22, electric power to the load 3 only during the time period T10 having a duration according to the dimming signal and to turn on the load 3 in a dimming manner in a time period of each half cycle of the alternating-current voltage Vac.

For example, when the load control system 1 is activated (i.e., the load 3 is turned on), or when the dimming level of the load 3 is changed, the adjuster 23 changes the length of the supply time period during which the power source 30 is supplied with electric power from the alternating-current voltage Vac of the alternating-current power source 2. In the present embodiment, the dimming controller 21 performs the reverse phase control. Moreover, the processing circuit 20 controls a semiconductor switch included in the power source 30 to switch between a state where the power source 30 is caused to perform generation operation of electric power and a state where the power source 30 is caused to stop the generating operation of the electric power. In the first supply time period TA1 from the zero crossing point to a timing at which the switch 10 is switched to the conduction state in each half period of the alternating-current voltage Vac, the processing circuit 20 performs control such that the power source 30 is in the state where the power source 30 is caused to execute the generation operation of the electric power. Thus, in the first supply time period TA1, the power source 30 is supplied with the electric power from the alternating-current power source 2 to generate electric power supplied to the processing circuit 20. At a timing at which the switch 10 is switched to the conduction state in each half period of the alternating-current voltage Vac, the processing circuit 20 switches the power source 30 to the state where the power source 30 is caused to stop the generation operation of the electric power. Then, at a timing (time t3, t7 in FIG. 3) at which the absolute value of the voltage value of the alternating-current voltage Vac decreases below a prescribed reference voltage (a voltage value which is of an extent that the load 3 does not operate) in a state where the switch 10 is controlled to be in the non-conduction state, the processing circuit 20 switches the power source 30 to a state where the power source 30 executes the generation operation of the electric power. Thus, in a second supply time period TA2 from the timing (time t3, t7) at which the absolute value of the voltage value of the alternating-current voltage Vac decreases below the reference voltage to a zero crossing point (time t4, t8), the power source 30 is supplied with the electric power from the alternating-current power source 2 to generate electric power (see FIG. 3). That is, the supply time period during which the power source 30 is supplied with the electric power from the alternating-current power source 2 to generate electric power to be supplied to the processing circuit 20 is a time period including the first supply time period TA1 and the second supply time period TA2. Here, the adjuster 23 of the present embodiment adjusts the duration (length) of the first supply time period TA1 to adjust the duration of the supply time period such that electric power necessary for operation of the processing circuit 20 is obtained. The adjuster 23 receives a charge voltage V1 of a first charging unit 321 described later from the power source 30 and adjusts the duration of the supply time period based on the charge voltage V1 of the first charging unit 321.

Moreover, in the present embodiment, the adjuster 23 adjusts the supply time period at a timing at which the brightness of the load 3 is changed, such as a timing at which the load 3 is turned on or a timing at which the dimming level is changed. Thus, even if adjusting the supply time period changes the conductive time period of the switch 10 and the brightness of the load 3 thus changes, a user is less likely to notice a change in brightness caused by adjusting the supply time period, so that it is possible to reduce an uncomfortable feeling given to a user. Note that the adjuster 23 may adjust the supply time period also in a normal state other than when the load 3 is turned on or when the dimming level is changed. Thus, even when the frequency or the voltage of the alternating-current power source 2 varies, adjusting the supply time period by the adjuster 23 makes it possible to reduce the possibility that the electric power supplied by the power source 30 becomes insufficient.

The operation receiving unit 24 receives, from the operation unit 50, an operation for changing the supply time period. The operation unit 50 includes the operation buttons 51 and 52. When a user operates the operation button 51, the operation receiving unit 24 receives, from the operation button 51, an operation signal for increasing the supply time period. Moreover, when the user operates the operation button 52, the operation receiving unit 24 receives, from the operation button 52, an operation signal for reducing the supply time period. When the operation receiving unit 24 receives the operation signal from the operation button 51 or 52, the adjuster 23 adjusts, based on the operation signal received by the operation receiving unit 24, the supply time period during which the power source 30 is supplied with the electric power from the alternating-current power source 2.

Next, the power source 30 will be described. The power source 30 is supplied with electric power from the alternating-current power source 2 to generate electric power supplied to the processing circuit 20 including the dimming controller 21 (the controller) and the wireless communication unit 22 (the additional functioning unit).

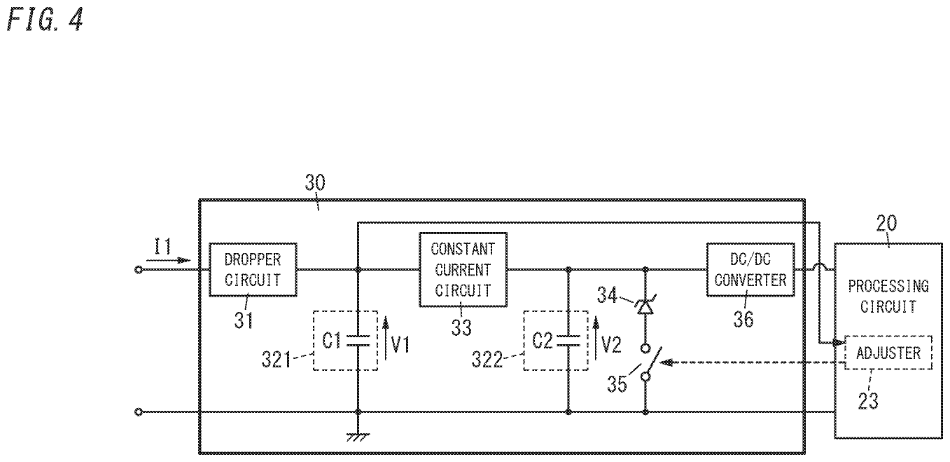

FIG. 4 is a circuit diagram illustrating an example of the power source 30. The power source 30 includes the first charging unit 321 and a second charging unit 322. Moreover, the power source 30 includes a dropper circuit 31, a constant current circuit 33, a Zener diode 34 which is a dummy load, a switch 35, and a DC/DC converter 36 which is a voltage stabilization circuit.

The power source 30 is electrically connected to the input terminal 61 via the diode D1 and is electrically connected to the input terminal 62 via the diode D2. Thus, the alternating-current voltage Vac applied between the input terminals 61 and 62 is subjected to full wave rectification by a diode bridge including the diodes D1 and D2 and respective parasitic diodes of the switch elements Q1 and Q2 and is then supplied to the power source 30. Thus, when the switch 10 is in the non-conduction state, the alternating-current voltage Vac after the full wave rectification (a pulsating voltage output from the diode bridge) is applied to the power source 30.

The dropper circuit 31 receives a voltage obtained by performing the full wave rectification of the alternating-current voltage Vac of the alternating-current power source 2 by a full-wave rectifier including the diodes D1 and D2 and the respective parasitic diodes of the switch elements Q1 and Q2. The dropper circuit 31 is a power supply circuit of a series regulator method. When the alternating-current voltage Vac after the full wave rectification is applied to the dropper circuit 31, the dropper circuit 31 reduces and smooths the voltage thus applied to generate a direct-current voltage. In the present embodiment, the processing circuit 20 controls a semiconductor switch included in the dropper circuit 31, which enables the input impedance of the dropper circuit 31 (i.e., the power source 30) to be changed. The processing circuit 20 is configured to switch the input impedance of the dropper circuit 31 to a first state where the input impedance is relatively high or a second state where the input impedance is relatively low. The processing circuit 20 changes the input impedance of the dropper circuit 31 to the first state to achieve a state where generation operation of the electric power by the power source 30 is stopped. The processing circuit 20 changes the input impedance of the dropper circuit 31 to the second state to achieve a state where generation operation of the electric power by the power source 30 is executed.

The first charging unit 321 includes a capacitor C1 such as an electrolytic capacitor. The first charging unit 321 is connected to an output side of the dropper circuit 31. When the alternating-current voltage Vac after the full wave rectification is applied to the dropper circuit 31, the first charging unit 321 is charged with a voltage output from the dropper circuit 31, and the charge voltage V1 is generated across the first charging unit 321.

The constant current circuit 33 is connected to the first charging unit 321. The second charging unit 322 is connected to an output side of the constant current circuit 33. The constant current circuit 33 generates a constant current by the charge voltage V1 of the first charging unit 321. The second charging unit 322 is charged by a current output from the constant current circuit 33.

The second charging unit 322 includes a capacitor C2 such as an electrolytic capacitor. The second charging unit 322 is connected to an output side of the first charging unit 321, specifically, the output side of the constant current circuit 33 connected to the first charging unit 321. The first charging unit 321 is charged with the charge voltage V1 of the first charging unit 321. That is, when the first charging unit 321 generates the charge voltage V1, the constant current circuit 33 outputs a current having a prescribed current value by using the first charging unit 321 as a power supply. The second charging unit 322 is charged with the current output from the constant current circuit 33. Here, the current output from the constant current circuit 33 is, for example, 2 mA.

Moreover, a series circuit of the Zener diode 34 which is a dummy load and the switch 35 is connected to the output side of the first charging unit 321. Here, the series circuit of the Zener diode 34 and the switch 35 is connected in parallel to the second charging unit 322. The switch 35 is switched ON or OFF by the adjuster 23. When the switch 35 is switched ON, a state is achieved where the Zener diode 34 (the dummy load) is connected to the output side of the first charging unit 321. The Zener diode 34 has a Zener voltage of, for example, 10 V. Thus, when the switch 35 is switched ON, electric power consumption by a circuit connected to the output side of the first charging unit 321 is set to 2 mA×10 V=20 mW and enters the maximum load state.

The DC/DC converter 36 is connected to an output side of the second charging unit 322. The DC/DC converter 36 outputs a stabilized voltage by using the second charging unit 322 as a power supply. The processing circuit 20 including the dimming controller 21 and the wireless communication unit 22 is connected to an output side of the DC/DC converter 36. As described above, the DC/DC converter 36 (the voltage stabilization circuit), which outputs the stabilized voltage by using the second charging unit 322 as a power supply, is connected to the output side of the second charging unit 322. The wireless communication unit 22 which is the additional functioning unit is connected to the output side of the DC/DC converter 36 (the voltage stabilization circuit). Thus, since the DC/DC converter 36 supplies the stabilized voltage to the processing circuit 20 including the dimming controller 21 and the wireless communication unit 22, the operation of the processing circuit 20 stabilizes. For example, the DC/DC converter 36 has an output voltage of 3.3 V and an output current of 5 mA, and the electric power consumption by the processing circuit 20 is 16.5 mW. Thus, electric power consumption is larger in the maximum load state in a case where the processing circuit 20 including the wireless communication unit 22 which is the additional functioning unit normally operates.

(3) Operation

(3.1) Operation of Power Source

When the alternating-current power source 2 is connected between the input terminals 61 and 62 via the load 3 at the time of installation of the load control system 1 of the present embodiment, the alternating-current voltage Vac applied between the input terminals 61 and 62 from the alternating-current power source 2 is rectified and is then supplied to the power source 30. In the power source 30, the alternating-current voltage Vac after the full wave rectification is input to the dropper circuit 31 and is converted by the dropper circuit 31 into a DC voltage having a prescribed voltage value, thereby generating the charge voltage V1 across the first charging unit 321. At this time, a current having a prescribed current value is output from the constant current circuit 33 and is charged into the second charging unit 322, thereby generating a charge voltage V2 across the second charging unit 322. The charge voltage V2 of the second charging unit 322 is stabilized by the DC/DC converter 36 and is supplied to the processing circuit 20 and the interface unit 40, and the processing circuit 20 and the interface unit 40 start operating.

When the processing circuit 20 is activated, the processing circuit 20 determines the frequency of the alternating-current power source 2 based on, for example, a voltage obtained by dividing the voltages of the input terminals 61 and 62 by the voltage dividing circuit. Then, the processing circuit 20 refers to, depending on the frequency thus determined, a numerical value table stored in memory in advance to set parameters such as various types of times. Here, at the time of installation, for example, a dimming signal at an OFF level is input from the interface unit 40 to the processing circuit 20, and the dimming controller 21 switches the switch 10 to the non-conduction state, thereby turning OFF the load 3.

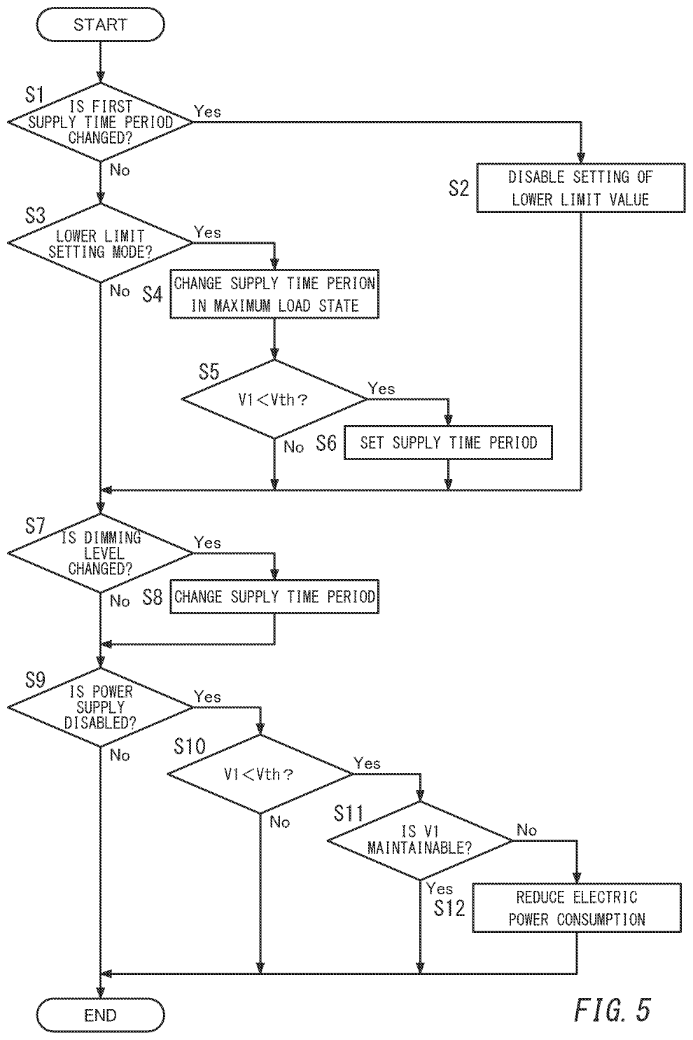

When in the load control system 1 of the present embodiment, the adjuster 23 switches the load 3 from the non-lighting state to a lighting state or changes the dimming level of the load 3, the adjuster 23 performs a process of adjusting the supply time period during which the power source 30 is supplied with the electric power from the alternating-current power source 2. Here, the process of adjusting the supply time period by the adjuster 23 will be described with reference to FIG. 5. Note that the initial value of the supply time period is set to an arbitrary time within a range which the duration of the supply time period can be included.

When the processing circuit 20 receives the dimming signal from the interface unit 40 to turn on the load 3 at a dimming level according to the dimming signal from the non-lighting state, the adjuster 23 performs the process of adjusting the supply time period. Specifically, the adjuster 23 sets the switch 35 to the ON state in a state where the wireless communication unit 22 is operating so that the Zener diode 34 is connected to the output side of the constant current circuit 33. The Zener diode 34 is a dummy load for achieving the maximum load state. The maximum load state is a state where electric power consumption by the wireless communication unit 22 is maximum in a state where the processing circuit 20 including the wireless communication unit 22 normally operates. The wireless communication unit 22 intermittently operates, and therefore, the electric power consumption of the wireless communication unit 22 varies in accordance with the operational state of the wireless communication unit 22. Moreover, when a degraded surrounding noise environment increases the communication errors, the surrounding noise environment also varies the electric power consumption by the wireless communication unit 22 if the wireless communication unit 22 increases transmission power of the radio signal. Thus, the Zener diode 34 which is the dummy load is selected such that when the Zener diode 34 is connected to the output side of the constant current circuit 33, the maximum load state where the electric power consumption by the wireless communication unit 22 is maximum is achieved.

The adjuster 23 monitors the charge voltage V1 of the first charging unit 321 in a state where the maximum load state is generated.

Here, if the charge voltage V1 of the first charging unit 321 is higher than or equal to a prescribed threshold voltage Vth, the adjuster 23 determines that electric power necessary for operation of the processing circuit 20 including the dimming controller 21 and the wireless communication unit 22 is secured. The adjuster 23 does not perform the process of changing the first supply time period TA1 (the supply time period) during which the power source 30 is supplied with electric power from the alternating-current power source 2 (S1: No), and the process proceeds to step S3.

In contrast, when the charge voltage V1 of the first charging unit 321 is lower than the threshold voltage Vth, the adjuster 23 determines that the electric power necessary for operation of the processing circuit 20 is not secured, and the adjuster 23 increases the first supply time period TA1 until the charge voltage V1 becomes higher than or equal to the threshold voltage Vth. If the adjuster 23 performs the process of changing the first supply time period TA1 (the supply time period) (S1: Yes), this means that the lower limit value of the first supply time period TA1 (the supply time period) is set, and therefore, the adjuster 23 disables setting of the lower limit value of the supply time period (S2), and the process proceeds to step S7.

When the process of changing the supply time period (the first supply time period TA1) is not performed at the time of turning ON the load 3, the adjuster 23 determines, for example, whether or not a lower limit setting mode is set by a setting switch disposed on the front surface of the housing 70 (S3).

Here, if the lower limit setting mode is set by the setting switch (S3: Yes), the adjuster 23 starts the process of setting the first supply time period TA1 (i.e., the supply time period) during which the power source 30 is supplied with electric power from the alternating-current voltage Vac.

The adjuster 23 sets the switch 35 to an ON state to achieve the maximum load state in a state where the wireless communication unit 22 is operating, and in the maximum load state, the adjuster 23 performs the process of adjusting the supply time period (S4). That is, the adjuster 23 monitors the charge voltage V1 of the first charging unit 321 while reducing the duration of the first supply time period TA1 in the maximum load state.

Here, if the charge voltage V1 of the first charging unit 321 does not decrease below the threshold voltage Vth (S5: No), the adjuster 23 sets the duration of the first supply time period TA1 to a minimum duration set in advance, and the process proceeds to step S7.

In contrast, if the charge voltage V1 of the first charging unit 321 decreases below the threshold voltage Vth (S5: Yes), the adjuster 23 sets the duration before the charge voltage V1 decreases below the threshold voltage Vth as the lower limit value of the first supply time period TA1 (i.e., the supply time period) (S6), and the process proceeds to step S7.

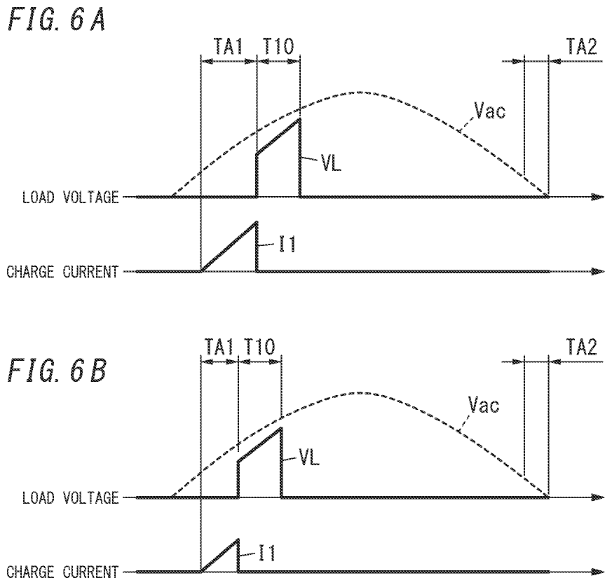

Here, FIGS. 6A and 6B show changes of the first supply time period TA1 before and after the lower limit value is set. FIG. 6A shows a load voltage VL at the time of activation of the load 3 and a charging current I1 that flows from the alternating-current power source 2 to the power source 30. FIG. 6B shows the load voltage VL and the charging current I1 after the lower limit value of the first supply time period TA1 is set. In the present embodiment, at an initial time (at the time of turning ON of the load 3), the first supply time period TA1 is set to a relatively long time so that electric power required by the power source 30 for the processing circuit 20 is secured. Since in the lower limit setting mode, the adjuster 23 adjusts the duration of the first supply time period TA1 to a lower limit value which is of an extent that the electric power supplied by the power source 30 to the processing circuit 20 is not insufficient, the maximum value of the time period during which the switch 10 is in the conduction state can be further increased. That is, setting the first supply time period TA1 to a minimum time enables the maximum value of the time period during which the switch 10 is in the conduction state to be further increased and the dimming level of the load 3 to be further increased.

In step S7, the adjuster 23 monitors, based on the dimming signal from the interface unit 40 or the wireless communication unit 22, whether or not the dimming level is changed.

In step S7, if the dimming level is changed (S7: Yes), the adjuster 23 sets the switch 35 to the ON state and connects the Zener diode 34 to the output side of the second charging unit 322, thereby achieving the maximum load state. The adjuster 23 monitors the charge voltage V1 of the first charging unit 321 in the maximum load state. If the charge voltage V1 is higher than or equal to the threshold voltage Vth, the adjuster 23 does not change the first supply time period TA1 (the supply time period) during which the power source 30 is supplied with electric power from the alternating-current power source 2. In contrast, if the charge voltage V1 is lower than the threshold voltage Vth, the adjuster 23 increases the first supply time period TA1 (the supply time period) during which the power source 30 is supplied with electric power from the alternating-current power source 2 (S8). As described above, the adjuster 23 sets the first supply time period TA1 (the supply time period) during which the power source 30 is supplied with electric power from the alternating-current power source 2, and then, the adjuster 23 proceeds with the process in step S9.

In contrast, if the dimming level does not change in step S7 (S7: No), the adjuster 23 proceeds with the process in step S9.

In step S9, the adjuster 23 monitors whether or not a power supply disabled state where electric power necessary for the processing circuit 20 is temporarily unobtainable occurs due to the occurrence of unexpected wireless noise, a voltage variation of the alternating-current voltage Vac of the alternating-current power source 2, or the like.

In step S9, if the adjuster 23 determines that the power supply disabled state occurs (S9: Yes), the adjuster 23 compares the charge voltage V1 of the first charging unit 321 to the threshold voltage Vth in terms of their magnitudes (S10).

Here, if the charge voltage V1 of the first charging unit 321 is higher than or equal to the threshold voltage Vth (S10: No), the adjuster 23 determines that the electric power supplied by the power source 30 to the processing circuit 20 is not insufficient, and the adjuster 23 ends the process.

In contrast, if the charge voltage V1 of the first charging unit 321 is lower than the threshold voltage Vth (S10: Yes), the adjuster 23 changes the first supply time period TA1 during which electric power is supplied from the alternating-current power source 2 within a range that the change in brightness of the load 3 is not noticeable. Even when the adjuster 23 changes the first supply time period TA1, the adjuster 23 can maintain the charge voltage V1 as long as the charge voltage V1 is higher than or equal to the threshold voltage Vth. That is, the adjuster 23 determines that the electric power supplied by the power source 30 to the processing circuit 20 is not insufficient (S11: Yes), and the adjuster 23 ends the process.

In contrast, when the adjuster 23 changes the first supply time period TA1, the adjuster 23 cannot maintain the charge voltage V1 if the charge voltage V1 of the first charging unit 321 is lower than the threshold voltage Vth. That is, the adjuster 23 determines that the electric power supplied by the power source 30 to the processing circuit 20 is insufficient (S11: No). At this time, the adjuster 23 increases the time cycle in which the wireless communication unit 22 is intermittently operated, or reduces the operation time for intermittent operation of the wireless communication unit 22, thereby performing a process of reducing electric power consumption by the wireless communication unit 22 (S12), and the adjuster 23 ends the process. Thus, the adjuster 23 can reduce the possibility that electric power supplied by the power source 30 to the processing circuit 20 is insufficient.

Moreover, in step S9, if the adjuster 23 determines that the power supply disabled state does not occur (S9: No), the adjuster 23 ends the process.

Then, while the load control system 1 is used, the adjuster 23 regularly or irregularly performs the process to adjust the supply time period during which the power source 30 is supplied with the electric power from the alternating-current power source 2. For example, the adjuster 23 increases the duration of the first supply time period TA1 to be longer than the minimum duration required to secure the electric power in the power source 30, and thereby, it is possible to reduce the possibility that electric power supplied from the power source 30 to the processing circuit 20 including the dimming controller 21 and the wireless communication unit 22 is insufficient. Moreover, the adjuster 23 at least sets the duration of the first supply time period TA1 to a time shorter than the duration obtained by adding a prescribed margin to the duration required to secure the electric power in the power source 30, and the adjuster 23 can thus reduce the possibility that the duration of the first supply time period TA1 is set to an unnecessarily long time. This enables the time period T10 during which the switch 10 is in the conduction state to be increased, and therefore, the brightness when the load 3 is turned on at the maximum dimming level is suppressed from being reduced. Moreover, if the duration of the first supply time period TA1 is increased, the voltage value of the alternating-current voltage Vac when the switch 10 is switched to the conduction state (time t1 in FIG. 3) increases. Thus, if the duration of the first supply time period TA1 is increased, the minimum value of the dimming level increases, but reducing the duration of the first supply time period TA1 enables the minimum value of the dimming level to be reduced as much as possible.

Note that in the description above, the adjuster 23 compares the charge voltage V1 of the first charging unit 321 to the threshold voltage Vth in terms of their magnitudes. However, two thresholds (a first threshold and a second threshold) may be set for the charge voltage V1, and the supply time period may be adjusted in accordance with the magnitude relationship between the charge voltage V1 and each of the two thresholds. Here, the first threshold is set to a value larger than the second threshold. When the charge voltage V1 of the first charging unit 321 decreases below the first threshold, the adjuster 23 increases the supply time period (the first supply time period TA1) to increase the charge voltage V1. Moreover, when the charge voltage V1 of the first charging unit 321 exceeds the second threshold, the adjuster 23 reduces the supply time period (the first supply time period TA1) to reduce the charge voltage V1. Thus, the adjuster 23 can adjust the first supply time period TA1 such that the charge voltage V1 of the first charging unit 321 has a voltage value higher than the first threshold and lower than the second threshold.

As described above, in the present embodiment, the adjuster 23 adjusts the supply time period (specifically, the first supply time period TA1) such the that electric power required by the dimming controller 21 (the controller) and the wireless communication unit 22 (the additional functioning unit) in the maximum load state is obtained. Thus, the adjuster 23 can automatically adjust the supply time period independently of an operation given by a user. The adjuster 23 adjusts the length of the first supply time period TA1 to adjust the supply time period but may adjust at least one length of the first supply time period TA1 and the second supply time period TA2 to adjust the supply time period.

Moreover, in the present embodiment, the adjuster 23 achieves the maximum load state by electrically connecting the Zener diode 34 which is the dummy load to the power source 30 in a state where the wireless communication unit 22 which is the additional functioning unit is operating. The Zener diode 34 which is the dummy load is a load different from the wireless communication unit 22 which is the additional functioning unit. Thus, in the present embodiment, the maximum load state is achievable in a state where the wireless communication unit 22 is communicatable with the control master 5, that is, in a state where the additional functioning unit can execute its function.

Moreover, in the present embodiment, the power source 30 includes the first charging unit 321 configured to be charged with the alternating-current voltage Vac from the alternating-current power source 2 to generate the charge voltage V1 and the second charging unit 322 configured to be charged with a charge voltage of the first charging unit 321. The Zener diode 34 which is the dummy load and the wireless communication unit 22 which is the additional functioning unit are electrically connected to an output side of the second charging unit 322. Then, based on the magnitude of the charge voltage V1 of the first charging unit 321, the adjuster 23 adjusts the supply time period (the first supply time period TA1) during which the power source 30 is supplied with the electric power from the alternating-current power source 2. Here, based on the magnitude of the charge voltage V1 of the first charging unit 321, the adjuster 23 can determine whether or not electric power to be supplied to the dimming controller 21 and the wireless communication unit 22 is insufficient. Thus, adjusting, by the adjuster 23, the supply time period TA1 based on the magnitude of the charge voltage V1 of the first charging unit 321 makes it possible to reduce the possibility that the electric power supplied by the power source 30 becomes insufficient.

Moreover, in the present embodiment, the load 3 includes a light source (an LED element) that can be turned on in a dimming manner. The controller (the dimming controller 21) switches the switch 10 to the conduction state or non-conduction state, thereby performing phase control of the alternating-current voltage supplied to the load 3. The adjuster 23 adjusts the supply time period (e.g., the first supply time period TA1) in a non-conductive time period except for the conductive time period (the time period T10) during which the switch 10 is in the conduction state in accordance with the dimming level of the light source. Thus, when adjusting the supply time period reduces the conduction time (the time period T10) of the switch 10, the brightness of the light source may be reduced, but since the adjuster 23 adjusts the supply time period in the maximum load state, it is possible to reduce the possibility that the electric power supplied by the power source 30 becomes insufficient.

(3.2) Load Control Operation

Next, load control operation of the load control system 1 of the present embodiment will be described with reference to FIG. 3.

First, the operation of the load control system 1 in a positive half period of the alternating-current voltage Vac will be described. The dimming controller 21 switches the switch 10 to the conduction state, in the positive half period of the alternating-current voltage Vac, based on a result of detection of the zero crossing point of the alternating-current voltage Vac, at a timing (the time t1 in FIG. 3) at which the first supply time period TA1 has elapsed since the zero crossing point (the time t0 of FIG. 3).

Here, in the positive half period of the alternating-current voltage Vac, the switch 10 is in the non-conduction state during the first supply time period TA1 from the zero crossing point (the time t0) of the alternating-current voltage Vac to the time t1, and the power source 30 can be supplied with electric power from the alternating-current power source 2. The power source 30 is supplied with the electric power from the alternating-current power source 2 to generate electric power to be supplied to the processing circuit 20 and the like and supplies the electric power thus generated to the processing circuit 20 and the like. Moreover, the processing circuit 20 controls the semiconductor switch of the dropper circuit 31 at the time t1 so that the input impedance of the dropper circuit 31 is in the first state, thereby achieving a state where the power source 30 stops generation operation of the electric power.

Moreover, the dimming controller 21 switches the switch 10 to the non-conduction state at the timing (the time t2 in FIG. 3) at which the time period T10 according to dimming level has elapsed since the time t1.

Thus, during the time period T10 from the time t1 to the time t2, electric power is supplied from the alternating-current power source 2 through the switch 10 to the load 3, and therefore, the load 3 is turned on at a prescribed dimming level.

When the absolute value of the voltage value of the alternating-current voltage Vac thereafter decreases below the prescribed reference voltage (the time t3 in FIG. 3), the processing circuit 20 switches the input impedance of the dropper circuit 31 to the second state, thereby achieving a state where the power source 30 executes the generation operation of the electric power. Thus, also during the second supply time period TA2 from the time t3 to the zero crossing point (the time t4 in FIG. 3) of the alternating-current voltage Vac, the power source 30 can be supplied with electric power from the alternating-current power source 2. Thus, the power source 30 can be supplied with electric power from the alternating-current power source 2 also during the second supply time period TA2 to generate electric power to be supplied to the processing circuit 20 and the like.

Next, the operation of the load control system 1 in the negative half period of the alternating-current voltage Vac will be described. The dimming controller 21 sets the switch 10 to the conduction state, in the negative half period of the alternating-current voltage Vac, based on a result of detection of the zero crossing point of the alternating-current voltage Vac, at the timing (the time t5 in FIG. 3) at which the first supply time period TA1 has elapsed since the zero crossing point (the time t4 in FIG. 3).

Here, in the negative half period of the alternating-current voltage Vac, the switch 10 is in the non-conduction state during the first supply time period TA1 from the zero crossing point (the time t4) of the alternating-current voltage Vac to the time t5, and the power source 30 can be supplied with electric power from the alternating-current power source 2. The power source 30 is supplied with the electric power from the alternating-current power source 2 to generate electric power to be supplied to the processing circuit 20 and the like and supplies the electric power thus generated to the processing circuit 20 and the like. Moreover, the processing circuit 20 controls the semiconductor switch of the dropper circuit 31 at the time t5 so that the input impedance of the dropper circuit 31 is in the first state, thereby achieving a state where the power source 30 stops generation operation of the electric power.

Moreover, the dimming controller 21 switches the switch 10 to the non-conduction state at the timing (the time t6 in FIG. 3) at which the time period T10 according to dimming level has elapsed since the time t5.

Thus, during the time period T10 from the time t5 to the time t6, electric power is supplied from the alternating-current power source 2 through the switch 10 to the load 3, and therefore, the load 3 is turned on at a prescribed dimming level.

When the absolute value of the voltage value of the alternating-current voltage Vac thereafter decreases below the prescribed reference voltage (the time t7 in FIG. 3), the processing circuit 20 switches the input impedance of the dropper circuit 31 to the second state, thereby achieving a state where the power source 30 executes the generation operation of the electric power. Thus, also during the second supply time period TA2 from the time t7 to the zero crossing point (the time t8 in FIG. 3) of the alternating-current voltage Vac, the power source 30 can be supplied with electric power from the alternating-current power source 2. Thus, the power source 30 can be supplied with electric power from the alternating-current power source 2 also during the second supply time period TA2 to generate electric power to be supplied to the processing circuit 20 and the like.

The load control system 1 alternately repeats the operation during the positive half period of the alternating-current voltage Vac and the operation during the negative half period of the alternating-current voltage Vac, thereby turning ON the load 3 in a dimming manner at the dimming level set by the dimming signal from the interface unit 40 or the wireless communication unit 22.

Note that when the dimming level of the dimming signal from the interface unit 40 or the wireless communication unit 22 is the “OFF level”, the dimming controller 21 maintains the switch 10 in the non-conduction state, thereby causing the impedance between the pair of input terminals 61 and 62 in the high impedance state. Thus, the load 3 enters the non-lighting state.

(4) Variation

The embodiment is a mere example of various embodiments of the present disclosure. Various modifications may be made depending on design and the like as long as the object of the present disclosure is achieved. Moreover, functions similar to those of the load control system 1 may be implemented by, for example, a computer program for controlling the load control system 1 or a non-transitory recording medium in which a program is stored. A program according to one aspect is a program configured to cause a computer system to execute a first process, a second process, and a third process. The first process is a process of switching the switch 10 between a conduction state and a non-conduction state. The switch 10 is electrically connected in series to a load 3 with respect to an alternating-current power source 2 and is configured to perform phase control of an alternating-current voltage Vac supplied to the load 3.

The second process is a process of causing an additional functioning unit (a wireless communication unit 22) to execute the process different from the switching operation of the switch 10. The third process is a process of adjusting, in a maximum load state, a supply time period during which a power source 30 is supplied with electric power from the alternating-current power source 2. The maximum load state is a state where electric power consumption by the additional functioning unit (the wireless communication unit 22) is maximum in a state where the additional functioning unit (the wireless communication unit 22) normally operates. The power source 30 is configured to receive the electric power supplied from the alternating-current power source 2 to generate electric power supplied to the additional functioning unit (the wireless communication unit 22). Moreover, the control method of the load control system 1 according to one aspect includes the first process, the second process, and the third process.

Variations of the embodiment will be described below. Note that any of the variations to be described below may be combined as appropriate.

The load control system 1 or a subject that executes the control method of the load control system 1 includes a computer system. The computer system includes, as principal hardware components, a processor and a memory. the processor executes a program stored in the memory of the computer system, thereby implementing functions as the load control system 1 or a subject that executes the control method of the load control system 1. The program may be stored in advance in the memory of the computer system. Alternatively, the program may also be downloaded through a telecommunications network or be distributed after having been recorded in some non-transitory storage medium, any of which is readable for the computer system. Examples of computer-system-readable non-transitory recording medium include memory cards, optical discs, and hard disk drives. The processor of the computer system includes one or more electronic circuits including a semiconductor integrated circuit (IC) or a large-scale integrated circuit (LSI). The integrated circuit such as IC or LSI mentioned herein may be referred to in another way, depending on the degree of the integration and may be integrated circuits called system LSI, very-large-scale integration (VLSI), or ultra-large-scale integration (ULSI). A field programmable gate array (FPGA), which is programmable after fabrication of the LSI, or a logical device which allows set-up of connections in LSI or reconfiguration of circuit cells in LSI may be used in the same manner. Those electronic circuits may be either integrated together on a single chip or distributed on multiple chips, whichever is appropriate. Those multiple chips may be integrated together in a single device or distributed in multiple devices without limitation.

Moreover, in the embodiment, the load control system 1 is constructed by one device which is to be provided in a single housing 70 but functions of the load control system 1 may be distributed in two or more devices. At least some functions of the load control system 1 may be constructed by, for example, cloud (cloud computing) or the like.

In the above-described embodiment, the adjuster 23 adjusts the supply time period such that electric power necessary for the controller and the additional functioning unit in the maximum load state is obtainable, but the adjuster 23 may change the supply time period (e.g., the first supply time period TA1) based on the operation received by the operation receiving unit 24.

When the operation receiving unit 24 receives through the operation button 51 an operation given by a user, the adjuster 23 increases the supply time period. When the operation receiving unit 24 receives through the operation button 52 an operation given by a user, the adjuster 23 reduces the supply time period. Moreover, the processing circuit 20 monitors the charge voltage V1 of the first charging unit 321 to determine whether or not the power source 30 generates required electric power necessary for operation of the dimming controller 21 and the wireless communication unit 22. When the processing circuit 20 determines that the power source 30 does not generate the required electric power necessary for operation of the dimming controller 21 and the wireless communication unit 22, the processing circuit 20 turns on the display lamp 71. When the processing circuit 20 determines that the power source 30 generates the required electric power necessary for operation of the dimming controller 21 and the wireless communication unit 22, the processing circuit 20 turns odd the display lamp 71. Thus, a user can operate the operation unit 50 while checking lighting/non-lighting of the display lamp 71 to adjust the supply time period such that the power source 30 generates the required electric power necessary for operation of the dimming controller 21 and the wireless communication unit 22.

Thus, the load control system 1 includes the operation receiving unit 24 configured to receive an operation for changing the supply time period, and the adjuster 23 changes the supply time period based on the operation received by the operation receiving unit 24. Thus, the adjuster 23 can change the supply time period in accordance with an operation given by a user.

In the above-described embodiment, the adjuster 23 adjusts the supply time period when the lower limit setting mode is set, or when the dimming level of the load 3 is changed (e.g., when the load 3 is turned on, when the dimming level of the load 3 is changed). However, the adjuster 23 may adjust the supply time period at other timings. For example, the adjuster 23 continuously monitors the state (e.g., the charge voltage V1) of the power source 30, and when the supply electric power of the power source 30 may become insufficient, the adjuster 23 may adjust the supply time period.

Moreover, in the above-described embodiment, the adjuster 23 achieves the maximum load state by connecting the Zener diode 34 which is the dummy load to the power source 30 in a state where the wireless communication unit 22 which is the additional functioning unit is operating, but the method for achieving the maximum load state is not limited to this example.

The adjuster 23 may achieve the maximum load state by connecting the Zener diode 34 which is the dummy load to the power source 30 in a state where the wireless communication unit 22 which is the additional functioning unit is stopped.

Moreover, the adjuster 23 may achieve the maximum load state by causing the wireless communication unit 22 which is the additional functioning unit to operate in a state where the electric power consumption is maximum without connecting the dummy load to the power source 30. That is, the adjuster 23 may achieve the maximum load state by causing the additional functioning unit to operate. Since the additional functioning unit itself can achieve the maximum load state, the advantage that the dummy load does not have to be provided is obtained.

Moreover, the dummy load is not limited to the Zener diode 34, the dummy load may be an impedance element such as a resistor.

In the above-described embodiment, the additional functioning unit is the wireless communication unit 22, but the additional functioning unit is not limited to the wireless communication unit 22. The additional functioning unit may be, for example, a speech recognition function for recognizing a voice command of a user. When the additional functioning unit is the speech recognition function, the process different from the switching operation is a process of recognizing user's speech to acquiring the command of the user. Here, the user's command is a control command for controlling the load 3, the processing circuit 20 controls the load 3 based on the user's command. Moreover, when the user's command is a command for requesting a response to a question of the user, the processing circuit 20 communicates with an external server device by a communication function for communication with the external server device to acquire, from the server device, contents of the response to the question. Then, the processing circuit 20 outputs the acquired contents of the response from, for example, a loudspeaker, or to a display monitor. Here, the speech recognition function which is the additional functioning unit performs a recognition process of user's speech, and the processing circuit 20 performs an operation based on the recognition result, thereby increasing the electric power consumption by the processing circuit 20 having the speech recognition function.

The load control system 1 of the above-described embodiment is applicable not only to the load 3 including LED element as the light source but also to light sources on which a capacitor-input-type circuit is mounted, which has a high impedance, and which can be turned on with a low current. Examples of such a light source include organic Electro Luminescence (EL) elements. Moreover, the load control system 1 is applicable to various loads 3 (e.g., a discharge lamp) as light sources.

Moreover, the load 3 controlled by the load control system 1 is not limited to the illumination load but may be, for example, a heater or a fan. When the load 3 is a heater, the load control system 1 adjusts average electric power supplied to the heater to adjust the amount of heat generated by the heater. Moreover, when the load 3 is a fan, the load control system 1 constitutes a regulator that adjusts the rotational speed of the fan.

Moreover, the switch 10 is not limited to a switch including the switch elements Q1 and Q2 including MOSFETs but may include, for example, two Insulated Gate Bipolar Transistors (IGBTs) connected reversely in series to each other. Moreover, in the switch 10, the rectifying element (the diode) for achieving the unidirectionally ON state is not limited to the parasitic diodes of the switch elements Q1 and Q2 but may be an external diode. The diode may be in the same package as the switch elements Q1 and Q2. Moreover, the switch 10 may be, for example, a semiconductor element having a double gate (dual gate) structure including a semiconductor material, such as gallium nitride (GaN), with a wide bandgap. This configuration enables conduction loss of the switch 10 to be reduced.

Moreover, in the power source 30, the first charging unit 321 may be charged, not via the dropper circuit 31, but directly from the alternating-current voltage Vac after full wave rectification. Moreover, the second charging unit 322 may be charged, not via the constant current circuit 33, but directly with the charge voltage V1 of the first charging unit 321.

Moreover, the switch 10 may be switched to the “forward ON state” instead of the “bidirectionally ON state”, or in contrast, the switch 10 may be switched to the “bidirectionally ON state” instead of the “forward ON state”. Moreover, the switch 10 may be switched to the “reversely ON state” instead of the “bidirectionally OFF state”, or in contrast, the switch 10 may be switched to the “bidirectionally OFF state” instead of the “reversely ON state”. That is, the state of the switch 10 in the conduction state or the non-conduction state is at least not changed.

Moreover, the control method of the switch 10 by the dimming controller 21 is not limited to the above-described example but may be, for example, a method of making the first control signal SG1 and the second control signal SG2 alternately be an “ON” signal at the same time cycle as the alternating-current voltage Vac. In this case, the switch 10 is conductive in a time period during which a switch element of the switch elements Q1 and Q2 which is at a high potential side of the alternating-current voltage Vac is ON. That is, this variation achieves so-called reverse phase control by which the pair of input terminals 61 and 62 become conductive to each other during a time period from the zero crossing point of the alternating-current voltage Vac to a time point in the half period. In this case, adjusting a phase difference between each of the first control signal and the second control signal and the alternating-current voltage Vac enables the conduction time of the switch 10 to be adjusted.

Moreover, the control method of the dimming controller 21 of the load control system 1 may be a universal control method compatible with both a normal phase control method and a reverse phase control method.

Moreover, an example in which the load control system 1 is a two-wire control system has been described in the embodiment above, but the load control system 1 is not limited to this example. The load control system 1 may be, for example, a so-called three-way switch to which three electric wires are connectable or a so-called four-way switch to which four electric wires are connectable. When the load control system 1 constitutes a three-way switch, two load control systems 1 are combined with each other to be able to switch an energization state of the load 3 at two locations, for example, at an upper floor and a lower floor of a staircase in a building.

Moreover, when two values such as measurement data and the like are compared with each other, “greater than or equal to” may be “greater than”. That is to say, when two values are compared with each other, it is arbitrarily changeable depending on selection of the threshold value whether or not the phrase “greater than or equal to” covers the situation where the two values are equal to each other. Similarly, “less than” may be “less than or equal to”.

### Summary

As described above, a load control system (1) of the first aspect includes a switch (10), a controller (21), an additional functioning unit (22), a power source (30), and an adjuster (23). The switch (10) is electrically connected in series to a load (3) with respect to an alternating-current power source (2) and is configured to perform phase control of an alternating-current voltage (Vac) supplied to the load (3). The controller (21) is configured to switch the switch (10) between a conduction state and a non-conduction state. The additional functioning unit (22) is configured to perform a process different from a switching operation of the switch (10). The power source (30) is configured to receive electric power supplied from the alternating-current power source (2) to generate electric power supplied to the controller (21) and the additional functioning unit (22). The adjuster (23) is configured to adjust, in a maximum load state, a supply time period (TA1) during which the power source (30) is supplied with the electric power from the alternating-current power source (2). The maximum load state is a state where electric power consumption by the additional functioning unit (22) is maximum in a state where the additional functioning unit (22) normally operates.

With this aspect, the adjuster (23) adjusts a supply time period during which the power source (30) is supplied with electric power from the alternating-current power source (2) in the maximum load state. Thus, as long as the supply time period is adjusted such that the supply electric power of the power source (30) in the maximum load state is not insufficient, it is possible to reduce the possibility that the supply electric power of the power source (30) is insufficient when electric power consumption by the additional functioning unit (the wireless communication unit 22) varies.

A load control system (1) of a second aspect referring to the first aspect further includes an operation receiving unit (24) configured to receive an operation for changing the supply time period (TA1). The adjuster (23) is configured to change the supply time period (TA1) based on the operation received by the operation receiving unit (24).

This aspect enables the adjuster (23) to change the supply time period (TA1) in accordance with an operation given by a user.

In a load control system (1) of a third aspect referring to the first aspect, the adjuster (23) is configured to adjust the supply time period (TA1) such that electric power necessary for the controller (21) and the additional functioning unit (22) in the maximum load state is obtained.

This aspect enables the adjuster (23) to adjust the supply time period (TA1) independently of an operation given by a user.

In a load control system (1) of a fourth aspect referring to any one of the first to third aspects, the adjuster (23) is configured to achieve the maximum load state by causing the additional functioning unit (22) to operate.

This aspect enables the maximum load state to be achieved by the additional functioning unit (22) itself.

In a load control system (1) of a fifth aspect referring to any one of the first to third aspects, the adjuster (23) is configured to achieve the maximum load state by electrically connecting a dummy load (34) to the power source (30). The dummy load (34) is a load different from the additional functioning unit (22).

With this aspect, the maximum load state is achieved by electrically connecting the dummy load (34) to the power source (30).

In a load control system (1) of a sixth aspect referring to any one of the first to third aspects, the adjuster (23) is configured to achieve the maximum load state by electrically connecting a dummy load (34) to the power source (30) in a state where the additional functioning unit (22) is operating. The dummy load (34) is a load different from the additional functioning unit (22).

With this aspect, the maximum load state is achievable by connecting the dummy load (34) to the power source (30) in a state where the additional functioning unit (22) is normally operated.

In a load control system (1) of a seventh aspect referring to the fifth or sixth aspect, the power source (30) includes a first charging unit (321) and a second charging unit (322). The first charging unit (321) is configured to be charged with the alternating-current voltage (Vac) from the alternating-current power source (2) to generate a charge voltage (V1). The second charging unit (322) is configured to be charged with the charge voltage (V1) of the first charging unit (321). The dummy load (34) and the additional functioning unit (22) are electrically connected to an output side of the second charging unit (322). The adjuster (23) is configured to adjust, based on a magnitude of the charge voltage (V1) of the first charging unit (321), the supply time period (TA1) during which the power source (30) is supplied with electric power from the alternating-current power source (2).

With this aspect, based on the magnitude of the charge voltage (V1) of the first charging unit (321), it is possible to determine whether or not electric power to be supplied to the controller (21) and the wireless communication unit (22) is insufficient. Thus, adjusting by the adjuster (23) the supply time period (TA1) based on the magnitude of the charge voltage V1 of the first charging unit (321) reduces the possibility that the supply electric power of the power source (30) is insufficient.

In a load control system (1) of an eighth aspect referring to the seventh aspect, a voltage stabilization circuit (36) is electrically connected to the output side of the second charging unit (322), the voltage stabilization circuit (36) being configured to output a stabilized voltage by using the second charging unit (322) as a power supply. The additional functioning unit (22) is electrically connected to an output side of the voltage stabilization circuit (36).

This aspect enables the additional functioning unit (22) to be supplied with a stabilized voltage.

In a load control system (1) of a ninth aspect referring to any one of the first to eighth aspects, the additional functioning unit (22) intermittently operates.

With this aspect, the additional functioning unit (22) intermittently operates, so that the possibility that supply electric power of the power source (30) is insufficient is reduced also when electric power consumption by the additional functioning unit (22) varies.

In a load control system (1) of a tenth aspect referring to any one of the first to ninth aspects, the load (3) includes a light source configured to be turned on in a dimming manner. The controller (21) switches the switch (10) between the conduction state and the non-conduction state to perform phase control of the alternating-current voltage (Vac) supplied to the load (3). The adjuster (23) is configured to adjust the supply time period (TA1) in a non-conductive time period except for a conductive time period during which the switch 10 is in the conduction state in accordance with a dimming level of the light source.

With this aspect, when adjusting the supply time period (TA1) reduces the conduction time of the switch (10), the brightness of the light source may be reduced, but adjusting the supply time period (TA1) in the maximum load state reduces the possibility that the supply electric power of the power source (30) is insufficient.

A program of an eleventh aspect is a program configured to cause a computer system to execute a first process, a second process, and a third process. The first process is a process of switching the switch (10) between a conduction state and a non-conduction state. The switch (10) is electrically connected in series to a load (3) with respect to an alternating-current power source (2) to perform phase control of the alternating-current voltage (Vac) supplied to the load (3). The second process is a process of causing an additional functioning unit (22) to execute a process different from a switching operation of the switch (10). The third process is a process of adjusting, in a maximum load state, a supply time period (TA1) during which a power source (30) is supplied with the electric power from the alternating-current power source 2. The maximum load state is a state where electric power consumption by the additional functioning unit (22) is maximum in a state where the additional functioning unit (22) normally operates. The power source (30) is configured to receive the electric power supplied from the alternating-current power source (2) to generate electric power to be supplied to the additional functioning unit (22).

With this aspect, the supply time period during which the power source (30) is supplied with electric power from the alternating-current power source (2) in the maximum load state is adjusted. Thus, as long as the supply time period is adjusted such that the supply electric power of the power source (30) in the maximum load state is not insufficient, it is possible to reduce the possibility that the supply electric power of the power source (30) is insufficient when electric power consumption by the additional functioning unit (the wireless communication unit 22) varies.

The aspects should not be construed as limiting, but various configurations (including variations) of the load control system (1) of the embodiment may be embodied by, for example, a (computer) program, or a non-transitory recording medium in which a program is stored.

The configurations according to the second to tenth aspects are not configurations essential for the load control system (1) and may thus be accordingly omitted.

### REFERENCE SIGNS LIST

1 LOAD CONTROL SYSTEM
2 ALTERNATING-CURRENT POWER SOURCE
3 LOAD
10 SWITCH
21 DIMMING CONTROLLER (CONTROLLER)
22 WIRELESS COMMUNICATION UNIT (ADDITIONAL FUNCTIONING UNIT)
   23 ADJUSTER
   24 OPERATION RECEIVING UNIT
   30 POWER SOURCE
   34 ZENER DIODE (DUMMY LOAD)
   36 DC/DC CONVERTER (VOLTAGE STABILIZATION CIRCUIT)
   321 FIRST CHARGING UNIT
   322 SECOND CHARGING UNIT
   TA1 FIRST SUPPLY TIME PERIOD (SUPPLY TIME PERIOD)
   V1 CHARGE VOLTAGE
   Vac ALTERNATING-CURRENT VOLTAGE

1. A load control system, comprising:
a switch electrically connected in series to a load with respect to an alternating-current power source, the switch being configured to perform phase control of an alternating-current voltage supplied to the load;
a controller configured to switch the switch between a conduction state and a non-conduction state;
an additional functioning unit configured to perform a process different from a switching operation of the switch;
a power source configured to receive electric power supplied from the alternating-current power source to generate electric power supplied to the controller and the additional functioning unit; and
an adjuster configured to adjust, in a maximum load state, a supply time period during which the power source is supplied with the electric power from the alternating-current power source, the maximum load state being a state where electric power consumption by the additional functioning unit is maximum in a state where the additional functioning unit normally operates.

2. The load control system of claim 1, further comprising:
an operation receiving unit configured to receive an operation for changing the supply time period, wherein
the adjuster is configured to change the supply time period based on the operation received by the operation receiving unit.

3. The load control system of claim 1, further comprising:
the adjuster is configured to adjust the supply time period such that electric power necessary for the controller and the additional functioning unit in the maximum load state is obtained.

4. The load control system of claim 1, wherein
the adjuster is configured to achieve the maximum load state by causing the additional functioning unit to operate.

5. The load control system of claim 1, wherein
the adjuster is configured to achieve the maximum load state by electrically connecting a dummy load to the power source, the dummy load being a load different from the additional functioning unit.

6. The load control system of claim 1, wherein
the adjuster is configured to achieve the maximum load state by electrically connecting a dummy load to the power source in a state where the additional functioning unit is operating, the dummy load being a load different from the additional functioning unit.

7. The load control system of claim 5, wherein
the power source includes
a first charging unit configured to be charged with the alternating-current voltage from the alternating-current power source to generate a charge voltage and
a second charging unit configured to be charged with the charge voltage of the first charging unit,
the dummy load and the additional functioning unit are electrically connected to an output side of the second charging unit, and
the adjuster is configured to adjust, based on a magnitude of the charge voltage of the first charging unit, the supply time period during which the power source is supplied with electric power from the alternating-current power source.

8. The load control system of claim 7, wherein
a voltage stabilization circuit is electrically connected to the output side of the second charging unit, the voltage stabilization circuit being configured to output a stabilized voltage by using the second charging unit as a power supply, and
the additional functioning unit is electrically connected to an output side of the voltage stabilization circuit.

9. The load control system of claim 1, wherein
the additional functioning unit intermittently operates.

10. The load control system of claim 1, wherein
the load includes a light source configured to be turned on in a dimming manner,
the controller switches the switch between the conduction state and the non-conduction state to perform phase control of the alternating-current voltage supplied to the load, and
the adjuster is configured to adjust the supply time period in a non-conductive time period except for a conductive time period during which the switch is in the conduction state in accordance with a dimming level of the light source.

11. A computer-readable non-transitory storage medium having stored thereon a program configured to cause a computer system to execute
a process of switching a switch between a conduction state and a non-conduction state, the switch being electrically connected in series to a load with respect to an alternating-current power source to perform phase control of the alternating-current voltage supplied to the load;
a process of causing an additional functioning unit to execute a process different from a switching operation of the switch; and
a process of adjusting, in a maximum load state, a supply time period during which a power source is supplied with electric power from the alternating-current power source, the maximum load state being a state where electric power consumption by the additional functioning unit is maximum in a state where the additional functioning unit normally operates, the power source being configured to receive the electric power supplied from the alternating-current power source to generate electric power supplied to the additional functioning unit.

12. The load control system of claim 2, wherein
the adjuster is configured to achieve the maximum load state by causing the additional functioning unit to operate.

13. The load control system of claim 3, wherein
the adjuster is configured to achieve the maximum load state by causing the additional functioning unit to operate.

14. The load control system of claim 2, wherein
the adjuster is configured to achieve the maximum load state by electrically connecting a dummy load to the power source, the dummy load being a load different from the additional functioning unit.

15. The load control system of claim 3, wherein
the adjuster is configured to achieve the maximum load state by electrically connecting a dummy load to the power source, the dummy load being a load different from the additional functioning unit.

16. The load control system of claim 2, wherein
the adjuster is configured to achieve the maximum load state by electrically connecting a dummy load to the power source in a state where the additional functioning unit is operating, the dummy load being a load different from the additional functioning unit.

17. The load control system of claim 3, wherein
the adjuster is configured to achieve the maximum load state by electrically connecting a dummy load to the power source in a state where the additional functioning unit is operating, the dummy load being a load different from the additional functioning unit.

18. The load control system of claim 6, wherein
the power source includes
a first charging unit configured to be charged with the alternating-current voltage from the alternating-current power source to generate a charge voltage and
a second charging unit configured to be charged with the charge voltage of the first charging unit,
the dummy load and the additional functioning unit are electrically connected to an output side of the second charging unit, and
the adjuster is configured to adjust, based on a magnitude of the charge voltage of the first charging unit, the supply time period during which the power source is supplied with electric power from the alternating-current power source.

19. The load control system of claim 18, wherein
a voltage stabilization circuit is electrically connected to the output side of the second charging unit, the voltage stabilization circuit being configured to output a stabilized voltage by using the second charging unit as a power supply, and
the additional functioning unit is electrically connected to an output side of the voltage stabilization circuit.

20. The load control system of claim 2, wherein
the additional functioning unit intermittently operates.
